(19) United States
(12) Patent Application Publication
(10) Pub. No.: US 2022/0258275 A1
(43) Pub. Date: Aug. 18, 2022

(54) WELDING ELECTRODE AND USE OF THE WELDING ELECTRODE

(71) Applicants: FRIEDRICH-ALEXANDER-UNIVERSITÄT ERLANGEN-NÜRNBERG, Erlangen (DE); WELDSTONE COMPONENTS GMBH, Köln (DE)

(72) Inventors: Stefan ROSIWAL, Bamberg (DE); Maximilian GÖLTZ, Möhrendorf (DE); Thomas HELMREICH, Nürnberg (DE); Andreas ENDEMANN, Bad Aibling (DE)

(21) Appl. No.: 17/618,174

(22) PCT Filed: Jun. 8, 2020
(86) PCT No.: PCT/EP2020/065857

§ 371 Date: Dec. 10, 2021

(30) Foreign Application Priority Data
Jun. 12, 2019 (DE) 10 2019 115 955.5
Dec. 17, 2019 (DE) 10 2019 134 727.0

(51) Int. Cl. B23K 11/30; B23K 11/18; B23K 35/22; C23C 16/27

(52) U.S. Cl. CPC B23K 11/30; B23K 11/185; B23K 2103/10; C23C 16/278; B23K 35/222

(57) ABSTRACT

The invention relates to a welding electrode for resistance welding, formed by a welding tool made of a metal, the welding tool having a contact surface that comes into contact with the workpiece to be welded. In order to avoid adhesion between the contact surface and a workpiece made, in particular of aluminum, it is suggested in the invention that the contact surface is made of diamond doped with boron.

The invention relates to a welding electrode for resistance welding according to the preamble of claim 1. It further relates to a use of such a welding electrode.

Welding electrodes for resistance welding, particularly resistance spot welding, are known, for example, from J. F. Key, T. H. Courtney: Refractory Metal Composite Tips for Resistance-Spot Welding of Galvanized Steel, Welding Research Supplement, 261-266, 1974.

Welding electrodes for resistance spot welding usually have a cap as the welding tool, which can be plugged onto an electrode holder of a resistance spot welding device. For roll seam welding a disc is used as the welding tool. To produce a welded joint between steel sheets, such welding electrodes are made, for example, of sintered CuAl₂O₃, CuCr- or CuCrZr-alloys.

In recent times, there has been a demand, particularly in the automotive industry, for the production of welded joints between aluminum sheets. Especially in the production of spot welded joints, conventional welding electrodes adversely stick to the aluminum sheets to be welded.

The object of the invention is to eliminate the disadvantages according to the prior art. In particular, a universal welding electrode shall be provided with which a large number of resistance welding joints or a large seam length between metal sheets is possible. According to a further object of the invention, a use of the welding electrode is to be indicated.

This task is solved by the features of claims 1 and 14. Practical embodiments of the invention are shown in the dependent patent claims.

According to the invention, a welding electrode for resistance welding is proposed in which the contact surface is formed of diamond doped with boron and/or phosphorus. —With the proposed welding electrode, it is surprisingly possible to produce more than 1,400 welded joints, in particular spot welded joints, between metal sheets, in particular aluminum sheets, without adhesion. In particular, in the case of the production of a spot-welded joint between two aluminum sheets, it appears, according to the present state of knowledge, that by means of the diamond layer according to the invention a passivation layer of Al₂O₃ formed on the surface of the aluminum sheets is mechanically broken through, at least in sections, so that the diamond layer comes into direct contact with the metallic aluminum. As a result, the contact resistance between the welding electrode and the aluminum sheet can be considerably reduced. This, in turn, prevents the aluminum sheet from melting in an area towards the contact surface of the welding electrode and thus from sticking to the welding electrode.

According to an advantageous embodiment, the diamond is doped with 500 to 20,000 ppm boron, preferably 2,000 to 10,000 ppm boron. The diamond may additionally or alternatively be doped with 500 to 20,000 ppm phosphorus. This enables a resistance welding process to be carried out with a current density of 30 kA/cm² or more. This corresponds to about 30 times the current density compared to the conventional resistance welding process for welding steel sheets. There, a current density of 1 kA/cm² is usually used. The possibility of using a particularly high current density makes it possible to carry out a resistance welding joint quickly. In particular, undesirable heating of large areas of the workpieces to be welded is avoided.

According to a further advantageous embodiment, the diamond is produced as a diamond layer by means of a CVD process. In the CVD process, the diamond layer is deposited from the gas phase in-situ on the welding electrode. It has been shown that a diamond layer produced in this way has surprisingly good durability even under the extreme conditions of resistance welding.

Advantageously, a thickness of the diamond layer is 0.5 to 50 μm, preferably 1 to 10 μm. The diamond layer advantageously has a surface roughness with an average roughness depth Rz>1 μm. A diamond coating with the above parameters is characterized by an improved service life of the welding electrode.

According to a further advantageous embodiment, more than 50% of the contact surface is formed by facets forming the (111) or (001) planes of diamond crystals, preferably of diamond single crystals grown together. A growth zone of the diamond layer opposite the contact surface is suitably in contact with an intermediate layer on the cap side. In particular, the diamond single crystals extend predominantly in a [111] or [110] direction from the intermediate layer to the contact surface. That is, the diamond single crystals extend from the intermediate layer to the contact surface such that their grain boundaries are predominantly approximately perpendicular to the contact surface. A diamond layer with the proposed formation is characterized by excellent electrical and thermal conductivity.

According to a further advantageous embodiment, the intermediate layer is formed from a metal carbide and/or nitride and/or boride compound of the first metal or of a second metal different from the first metal. In particular, the first and/or second metal forms a carbide and/or nitride and/or boride compound stable up to a temperature of 800° C. The first and/or second metal may in particular be formed from one or more of Cr, Ti, Nb, Mo, W, Ta. The intermediate layer can either be formed in-situ directly during the CVD process or can be formed separately at a temperature of 600° C. to 1,050° C.

For example, the first metal may be W which contains Cu as an alloy component. In this case, the intermediate layer can be formed directly in the CVD process by which the diamond layer is deposited. In this case, WC is formed as the intermediate layer. For example, it may also be that the first metal is formed of W containing Fe as an alloy component. In this case, a TiN layer is deposited on the first metal as an intermediate layer in a first CVD process. This layer may be doped with B. Subsequently, the diamond layer is deposited on the intermediate layer in a second CVD process.

The first metal may preferably include Cu, Fe or even Ag as an alloy component.

Apart from the first metal, the welding tool may also be formed in sections from a third metal. The third metal may comprise Cu as a main component. That is, the welding tool may be made of, for example, a W- or Mo-alloy at least in a section forming the contact surface. Incidentally, the welding tool may also be made of another metal, for example a Cu-alloy. Such a welding tool can be manufactured relatively inexpensively.

The welding tool can be a cap for fitting onto an electrode holder of a resistance spot welding device. However, the welding tool can also be a disc for a roller seam welding device.

According to a further provision of the invention, it is proposed to use the welding electrode according to the invention for making a welded joint between workpieces made of a fourth metal having a passivating metal oxide layer.

The term “metal” is to be understood generally in the sense of the present invention. That is, it may also refer to an alloy.

The “fourth metal” is understood to be a metal which spontaneously forms an oxide layer on its surface when in contact with air. —The fourth metal is preferably selected from the following group: Al, Mg, Ni, Ti, Zn, Cr, Fe, Nb, Ta, Cu. In particular, aluminum spontaneously forms a passivation layer of Al₂O₃ on its surface. Al₂O₃ is electrically insulating and has a high hardness (Vickers hardness about 2,000). The diamond layer provided on the welding electrode according to the invention has a higher hardness, namely Vickers hardness 7,000 to 10,000. Consequently, the welding electrode according to the invention succeeds in breaking through the passivating layer forming, for example, on aluminum sheets, so that direct electrical contact is established between the diamond layer and the metallically conductive section below the passivating layer. As a result, the welding electrode according to the invention succeeds in producing a welded joint without the welding electrode sticking to the sheet to be welded. —The effect described also applies to other fourth metals which form a passivating metal oxide layer, e.g. Al, Mg, Ni, Ti, Zn, Cr, Fe, Nb, Ta, Cu.

It is expedient that the welded joint is produced by means of resistance spot welding. However, with a corresponding design of the welding electrode according to the invention, it is also conceivable, for example, to produce linear welded joints.

In the following, an embodiment of the invention will be explained in more detail with reference to the drawings. It shows:

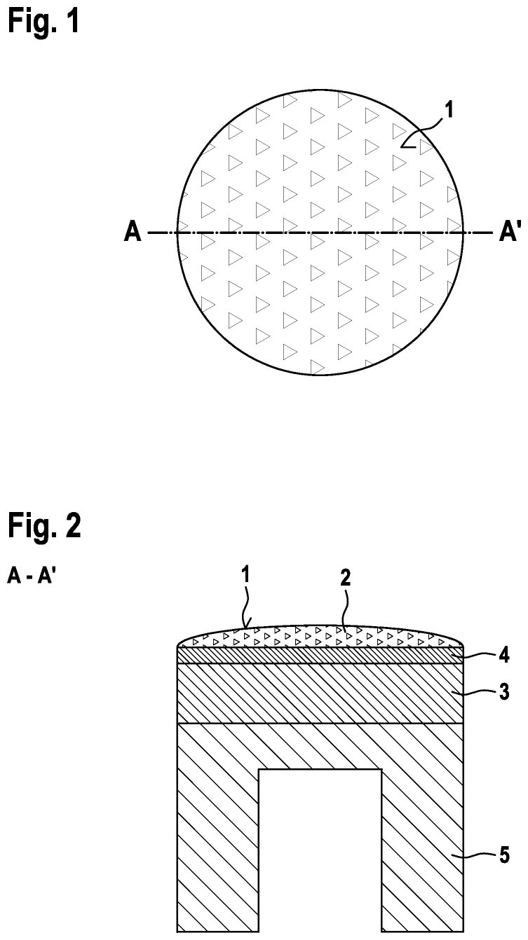

FIG. 1 a top view of a welding cap,

FIG. 2 a sectional view through the welding cap according to the sectional line A-A′ in FIG. 1,

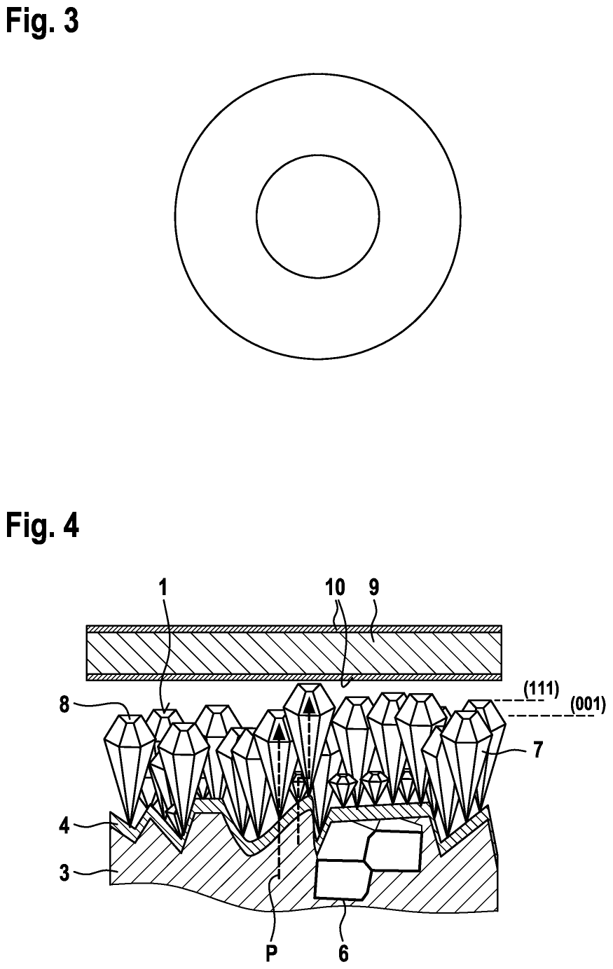

FIG. 3 a bottom view according to FIG. 1 and

FIG. 4 a schematic sectional view through the surface of a welding cap and a sheet to be welded.

FIGS. 1 to 3 show a welding electrode in the form of a cap or welding cap. The welding electrode has a contact surface 1 which forms the free surface of a diamond layer 2. Reference numeral 3 denotes a portion formed, for example, of W or Mo or an alloy containing Mo or W as a main component. Reference sign 4 denotes an intermediate layer, which in the specific example is substantially formed of WC or MoC. The intermediate layer 4 can be formed in-situ during the manufacture of the diamond layer 2 by means of a CVD process.

Reference numeral 5 indicates a base portion of the welding cap. The base portion 5 may be made of a third metal different from the first metal forming the portion 3. A third metal may be chosen to manufacture the base portion 5, which is less expensive than the first metal used to manufacture the portion 3. For example, the base section 5 may be formed of pure copper or of a copper-alloy, in particular CuAl₂O₃-, CuCr- or CuCrZr-alloys. —It may of course also be the case that the base portion 5 is omitted and the cap is formed from the first metal forming the portion 3.

According to a further embodiment not shown in the figures, it is also possible that the section 3 is omitted. In this case, the welding cap is made of a conventional copper-alloy, for example. In this case, the intermediate layer 4 must be applied separately. The intermediate layer may be formed of carbide forming metals. For example, the intermediate layer may comprise Ti. The diamond layer 2 can then be deposited on such an intermediate layer 4 by means of a CVD process.

FIG. 4 schematically shows the section 3 which is made of a W- or Mo-alloy. The alloy may have a grain boundary phase 6 at the grain boundaries, only some of which are shown here by way of example, which is formed from Fe, Ni, Co or Cu, for example. In the case of an in-situ coating, it is convenient to remove the grain boundary phase 6 superficially by etching and/or particle blasting. This increases the strength of the bond between the diamond layer 2 and the intermediate layer 4.

The diamond crystals 7 extending from the intermediate layer 4 are more than 50% diamond single crystals. The facets of the diamond crystals 7, denoted by the reference sign 8, are formed from either the (111) plane or the (001) plane. The reference sign P denotes arrows representing the direction of current flow through the diamond layer 2. The current flow is parallel to the [111] direction as well as the [110] direction of the diamond crystals 7.

The contact surface 1 of the diamond layer 2 is formed by the totality of the facets 8. Opposite the contact surface 1 is a workpiece 9 to be welded, which is made of an aluminum-alloy, for example. The workpiece 9 has a metal oxide layer 10 on its surface.

Although it is not shown in the figures, the welding tool may be formed of a disc instead of the cap. Such a disc is used in roller seam welding devices. In this case, the contact surface 1 is formed on the peripheral edge of the disc. The section 3 and, if applicable, the base section 5 are arranged in a radially inward position in the disc in a sequence analogous to that of the cap shown in FIGS. 1 to 3.

To produce a welded joint between the workpiece 9 and another workpiece (not shown here), the diamond layer 2 is pressed against the metal oxide layer 10. A current density in the range of 5 to 60 kA/cm², preferably in the range of 10 to 20 kA/cm², is generated. In this process, the workpiece 9 welds to a further workpiece (not shown here) arranged opposite, which is pressed against the workpiece 9 with a further welding electrode (not shown here) according to the invention.

With the proposed welding electrode, more than 1,000 spot welds can be performed, especially on aluminum sheets, without adhesion occurring between the welding electrode and the aluminum sheets.

### LIST OF REFERENCE SIGNS

1 Contact surface
2 Diamond layer
3 Section
4 Intermediate layer
5 Base section
6 Grain boundary phase
7 Diamond crystal
8 Facet
9 Workpiece
10 Metal oxide layer
P Arrow

1. A welding electrode for resistance welding, formed from a welding tool which is made at least in sections from a first metal and has a contact surface (1) which comes into contact with the workpiece (9) to be welded,
wherein
the contact surface (1) is formed of diamond doped with boron and/or phosphorus.

2. The welding electrode of claim 1, wherein the diamond is doped with 500 to 20,000 ppm boron.

3. The welding electrode according to claim 1, wherein the diamond is produced as a diamond layer (2) by CVD process.

4. The welding electrode according to claim 1, wherein a thickness of the diamond layer (2) is 0.5 to 50 μm, preferably 1 to 10 μm.

5. The welding electrode according to claim 1, wherein the diamond layer (2) has a surface roughness with an average roughness depth of Rz>1 μm.

6. The welding electrode according to claim 1, wherein the contact surface (1) is formed by more than 50% of facets forming the (111) or (001) planes of diamond crystals, preferably of diamond single crystals.

7. The welding electrode according to claim 1, wherein a growth zone of the diamond layer (2) opposite the contact surface (1) is in contact with an intermediate layer (4).

8. The welding electrode according to claim 1, wherein the diamond crystals (7) extend in a [111] or [110] direction from the intermediate layer (4) to the contact surface (1).

9. The welding electrode according to claim 1, wherein the intermediate layer (4) is formed of a carbide and/or nitride and/or boride compound of the first metal or of a second metal different from the first metal.

10. The welding electrode according to claim 1, wherein the first and/or second metal forms a carbide and/or nitride and/or boride compound stable up to a temperature of 800° C.

11. The welding electrode according to claim 1, wherein the first and/or second metal is formed of one or more of the following elements: Cr, Ti, Nb, Mo, W, Ta.

12. The welding electrode according to claim 1, wherein the welding tool is formed in sections from a third metal.

13. The welding electrode according to claim 1, wherein the third metal contains Cu as a main component.

14. Use of the welding electrode according to claim 1 for making a resistance welded joint between workpieces (9) made of a fourth metal with a passivating metal oxide layer (10).

15. Use according to claim 14, wherein the resistance welded joint is made by resistance spot welding, resistance projection welding or resistance seam welding.

16. Use according to claim 14, wherein the fourth metal is selected from the following group: Al, Mg, Ni, Ti, Zn, Cr, Fe, Nb, Ta, Cu.
